(19) United States
(12) Patent Application Publication
(10) Pub. No.: US 2025/0062212 A1
(43) Pub. Date: Feb. 20, 2025

(54) SEMICONDUCTOR PACKAGES AND ELECTRONIC DEVICES INCLUDING THE SAME

(71) Applicant: SAMSUNG ELECTRONICS CO., LTD., Suwon-si (KR)

(72) Inventors: Ki Won BAEK, Suwon-si (KR); Dong Ok KWAK, Suwon-si (KR)

(21) Appl. No.: 18/604,973

(22) Filed: Mar. 14, 2024

(30) Foreign Application Priority Data
Aug. 18, 2023 (KR) 10-2023-0108209
Aug. 31, 2023 (KR) 10-2023-0115554

(51) Int. Cl. H01L 23/498; H01L 23/00; H01L 23/48; H01L 23/62; H01L 25/18

(52) U.S. Cl. CPC H01L 23/49838; H01L 23/481; H01L 23/49816; H01L 23/62; H01L 24/08; H01L 24/16; H01L 25/18; H01L 2224/08225; H01L 2224/16145; H01L 2224/16225; H01L 2225/06513; H01L 2225/06517; H01L 2924/1431; H01L 2924/1436

(57) ABSTRACT

There is provided a semiconductor package comprising: a substrate that includes a first surface and a second surface, wherein the second surface is opposite to the first surface; a first connection member and a second connection member on the second surface of the substrate; an upper pad on the first surface of the substrate, wherein the upper pad is electrically connected to the first connection member; a circuit pattern on the first surface of the substrate, wherein the circuit pattern is electrically connected to the second connection member; an upper passivation film on the first surface of the substrate, wherein the upper passivation film at least partially exposes the upper pad and the circuit pattern; a bump on the upper pad; and a semiconductor chip on the bump, wherein the circuit pattern is electrically separated from the semiconductor chip.

### CROSS-REFERENCE TO RELATED APPLICATION

This application claims priority from Korean Patent Application No. 10-2023-0108209 filed on Aug. 18, 2023 and No. 10-2023-0115554 filed on Aug. 31, 2023 in the Korean Intellectual Property Office and all the benefits accruing therefrom under 35 U.S.C. 119, the contents of which in its entirety are herein incorporated by reference.

### BACKGROUND

The present disclosure relates to semiconductor packages and electronic devices including the same.

With the development of electronic industry, demands for high functionality, high speed and miniaturization of electronic components have been increased. In response to this trend, a method of stacking and packaging various semiconductor chips on one package substrate or a method of stacking a package on another package may be used. For example, a package in which a flip chip type semiconductor chip is packaged may be used.

The package to which a flip chip type is applied may be packaged on a printed circuit board (PCB) substrate. At this time, a short may occur between the packaged chip and the substrate or between the chip and a PCB circuit pattern. The short may aggravate durability of a product, which includes a semiconductor package, and may deteriorate reliability of the semiconductor package.

### SUMMARY

An object of the present disclosures may be providing semiconductor packages in which durability and reliability are improved.

Another object of the present disclosures may be providing electronic devices including semiconductor packages in which durability and reliability are improved.

However, the objects of the present disclosures are not limited to those mentioned above and additional objects of the present disclosures, which are not mentioned herein, will be clearly understood by those skilled in the art from the following description of the present disclosure.

According to an aspect of the present disclosure, there is provided a semiconductor package comprising: a substrate that includes a first surface and a second surface, wherein the second surface is opposite to the first surface; a first connection member and a second connection member on the second surface of the substrate; an upper pad on the first surface of the substrate, wherein the upper pad is electrically connected to the first connection member; a circuit pattern on the first surface of the substrate, wherein the circuit pattern is electrically connected to the second connection member; an upper passivation film on the first surface of the substrate, wherein the upper passivation film at least partially exposes the upper pad and the circuit pattern; a bump on the upper pad; and a semiconductor chip on the bump, wherein the circuit pattern is electrically separated from the semiconductor chip.

According to another aspect of the present disclosure, there is provided an electronic device comprising: a semiconductor package; and a controller that is electrically connected to the semiconductor package, wherein the controller is configured to measure a current of the semiconductor package, wherein the semiconductor package comprises: a substrate that includes a first surface and a second surface, wherein the second surface is opposite to the first surface; a circuit pattern and a plurality of upper pads on the first surface of the substrate; an upper passivation film on the first surface of the substrate; a first connection member on the second surface of the substrate, wherein the first connection member is electrically connected to the plurality of upper pads; a second connection member on the second surface of the substrate, wherein the second connection member is electrically connected to the circuit pattern; and each of the first connection member and the second connection member is electrically connected to the controller.

According to still another aspect of the present disclosure, there is provided an electronic device comprising: a semiconductor package; and a controller that is electrically connected to the semiconductor package and is configured to measure a current in the semiconductor package, wherein the semiconductor package comprises a substrate that includes a first surface and a second surface, wherein the second surface is opposite to the first surface; a circuit pattern and a plurality of upper pads on the first surface of the substrate; an upper passivation film on the first surface of the substrate, wherein the upper passivation film at least partially exposes the circuit pattern and the plurality of upper pads; a first connection member on the second surface of the substrate, wherein the first connection member is electrically connected to a subset of the plurality of upper pads; a second connection member on the second surface of the substrate, wherein the second connection member is electrically connected to the circuit pattern; and a daisy chain circuit in the substrate, wherein the daisy chain circuit includes a first conductive pattern and a second conductive pattern, wherein the first conductive pattern is electrically connected to the first connection member, wherein the second conductive pattern is electrically connected to the second connection member, and wherein the controller is configured to measure a current between the first connection member and the second connection member.

### BRIEF DESCRIPTION OF THE DRAWINGS

The above and other aspects and features of the present disclosures will become more apparent by describing in detail illustrative embodiments thereof with reference to the attached drawings, in which:

FIG. 1 is an example block diagram illustrating an electronic device including a semiconductor package according to some embodiments;

FIG. 2 is an example cross sectional view illustrating a semiconductor package according to some embodiments;

FIG. 3 is an example schematic view illustrating a semiconductor package according to some embodiments;

FIG. 4 is an example schematic view illustrating a semiconductor package according to some embodiments;

FIG. 5 is an example cross sectional view illustrating a semiconductor package according to some embodiments;

FIGS. 6 and 7 are example views illustrating a semiconductor package according to some embodiments;

FIG. 8 is an example view illustrating a semiconductor package according to some embodiments;

FIG. 9 is a view illustrating an electronic device according to some embodiments;

FIG. 10 is a view illustrating an electronic device according to some embodiments;

FIG. 11 is a view illustrating a semiconductor package and a main board of FIG. 10.

### DETAILED DESCRIPTION OF THE DISCLOSURE

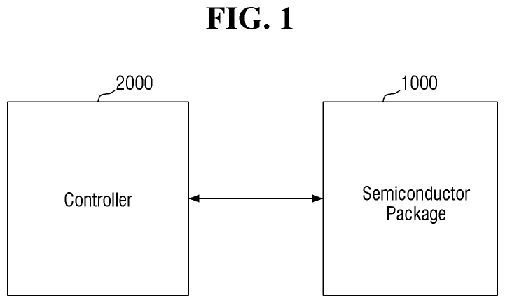

Hereinafter, a semiconductor package and an electronic device including the same according to some embodiments will be described with reference to FIGS. 1 to 11.

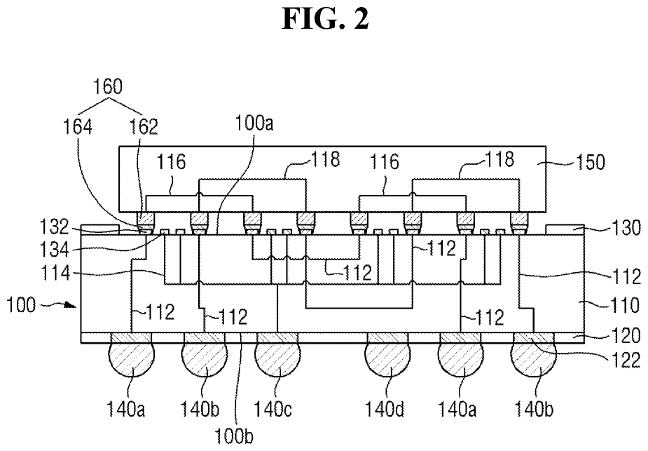

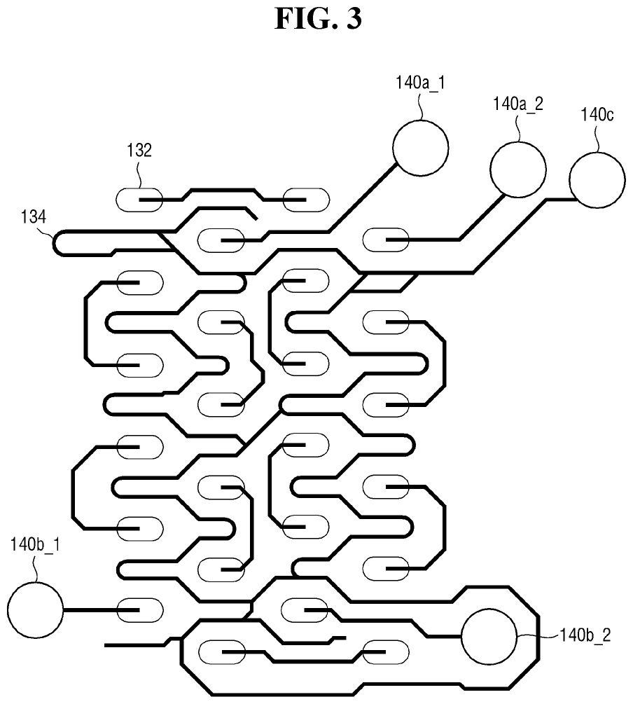

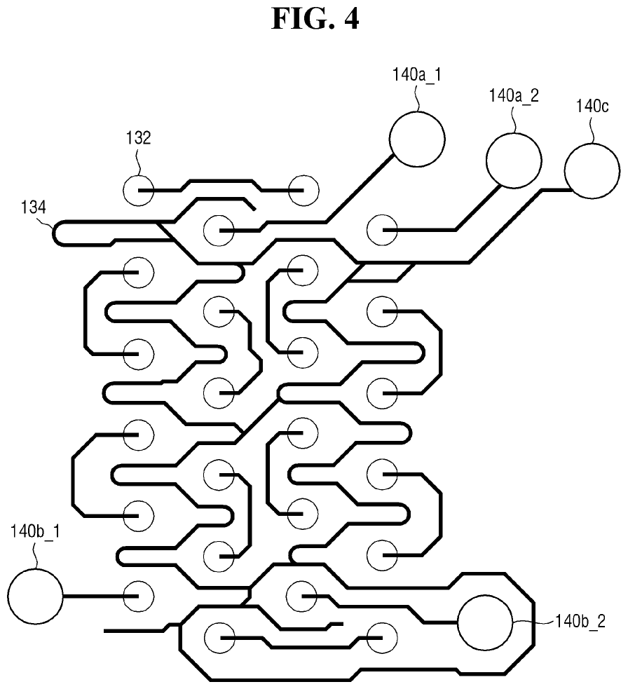

FIG. 1 is an example block diagram illustrating an electronic device including a semiconductor package according to some embodiments. FIG. 2 is an example cross sectional view illustrating a semiconductor package according to some embodiments. FIG. 3 is an example schematic view illustrating a semiconductor package according to some embodiments. FIG. 4 is an example schematic view illustrating a semiconductor package according to some embodiments.

Referring to FIG. 1, the electronic device may include a controller 2000 and a semiconductor package 1000.

The controller 2000 may be electrically connected to the semiconductor package 1000. In detail, the controller 2000 may provide an electrical signal to the semiconductor package 1000. For example, the controller 2000 may provide a voltage to allow a current to flow in the semiconductor package 1000. The controller 2000 may select IN/OUT of a portion connected (e.g., electrically connected) to the semiconductor package 1000 to flow the current. The controller 2000 may measure the current flowing in the semiconductor package 1000. A user or the controller 2000 may detect a short or open (of the semiconductor package 1000) based on the measured current. In some embodiments, the controller 2000 may detect a short or open (of the semiconductor package 1000) by measuring resistance of the semiconductor package 1000. It will be understood that when an element or layer is referred to as being “connected to”, or “coupled to” another element or layer, it may be directly on, connected to, or coupled to the other element or layer, or one or more intervening elements or layers may be present. In contrast, when an element is referred to as being “directly coupled,” “directly connected,” or “directly responsive” to, or “directly on,” another element, there are no intervening elements present. In addition, “electrical connection” conceptually includes a physical connection and a physical disconnection. In addition, it will also be understood that when an element or layer is referred to as being “between” two elements or layers, it may be the only element or layer between the two elements or layers, or one or more intervening elements or layers may also be present. As used herein, the term “and/or” includes any and all combinations of one or more of the associated listed items.

Referring to FIG. 2, the semiconductor package (e.g., the semiconductor package 1000 in FIG. 1) according to some embodiments may include a first substrate 100, a first connection member 140a, a second connection member 140b, a third connection member 140c, a fourth connection member 140d, a first bump 160 and a first semiconductor chip 150.

The first substrate 100 may be a package substrate. For example, the first substrate 100 may be a printed circuit board (PCB) or the like. In some embodiments, the first substrate 100 may be, for example, a wafer level package (WLP) substrate fabricated at a wafer level. The first substrate 100 may include a lower surface and an upper surface, which are opposite to each other. A first surface 100a and a second surface 100b of the first substrate 100 may face each other. The first surface 100a and the second surface 100b of the first substrate 100 may be opposite to each other. In some embodiments, the first surface 100a of the first substrate 100 may be referred to as the upper surface of the first substrate 100, and the second surface 100b of the first substrate 100 may be referred to as the lower surface of the first substrate 100.

The first substrate 100 may include a first insulating layer 110. A first conductive pattern 112 and a second conductive pattern 114 may be disposed in the first insulating layer 110. A first lower passivation film 120, a first lower pad 122, a first upper passivation film 130, a first upper pad 132, and a circuit pattern 134 may be disposed on the first insulating layer 110. In some embodiments, an upper surface of the first insulating layer 110 may be the upper surface (e.g., the first surface 100a) of the first substrate 100, and an lower surface of the first insulating layer 110 may be the lower surface (e.g., the second surface 100b) of the first substrate 100. The first lower passivation film 120 and the first lower pad 122 may be disposed on the lower surface of the first insulating layer 110. The first upper passivation film 130, the first upper pad 132, and the circuit pattern 134 may be disposed on the upper surface of the first insulating layer 110.

The first upper passivation film 130 may be disposed on the first surface 100a of the first substrate 100. The first upper passivation film 130 may cover (or overlap) at least a portion of the first surface 100a of the first substrate 100 in a vertical direction perpendicular to the first surface 100a of the first substrate 100. The first upper passivation film 130 may at least partially expose the first upper pad 132 and the circuit pattern 134, which are disposed on the first substrate 100 (e.g., on the first surface 100a of the first substrate 100). As used herein, “an element A overlapping an element B in a direction X” (or similar language) means that there is at least one line that extends in the direction X and intersects both the elements A and B.

The first upper pad 132 may be disposed on the first surface 100a of the first substrate 100. The first upper pad 132 may be exposed on the first surface 100a of the first substrate 100. The first upper pad 132 may electrically connect the first conductive pattern 112 and the first bump 160.

In the semiconductor package (e.g., the semiconductor package 1000 in FIG. 1) according to some embodiments, the first upper pad 132 may have an oblong shape as shown in FIG. 3. The first upper pad 132 may have an oblong shape when viewed in a plan view. In some embodiments, the first upper pad 132 may have a circular shape as shown in FIG. 4. The first upper pad 132 may have a circular shape when viewed in a plan view, but is not limited thereto.

The circuit pattern 134 may be disposed on the first surface 100a of the first substrate 100. The circuit pattern 134 may be exposed on the first surface 100a of the first substrate 100. The circuit pattern 134 may be spaced apart from the first bump 160. For example, the circuit pattern 134 may be space apart from the first bump 160 in a first horizontal direction and/or in a second horizontal direction parallel with the first surface 100a of the first substrate 100). The first horizontal direction may intersect with the second horizontal direction. For example, the circuit pattern 134 may be (electrically) separated (e.g., insulated) from the first bump 160. The circuit pattern 134 may be (electrically) separated (e.g., insulated) from the first semiconductor chip 150. The circuit pattern 134 may be electrically connected to the second conductive pattern 114.

In the vertical direction perpendicular to the first surface 100a of the first substrate 100, a height of the first upper passivation film 130 may be greater than that of the first upper pad 132. In the vertical direction perpendicular to the first surface 100a of the first substrate 100, the height of the first upper passivation film 130 may be greater than that of the circuit pattern 134. Herein, a height in the vertical direction may refer to a (farthest) distance from the first surface 100a (or the second surface 100b) of the first substrate 100 in the vertical direction. For example, when a height of element A is greater than a height of element B, the farthest point of the element A in the vertical direction may be farther than the farthest point of the element B in the vertical direction from the first surface 100a of the first substrate 100.

The first lower passivation film 120 may be disposed on the second surface 100b of the first substrate 100. The first lower pad 122 may be disposed on the second surface 100b of the first substrate 100. The first lower passivation film 120 may at least partially cover (or overlap in the vertical direction) the second surface 100b of the first substrate 100 and at least partially expose the first lower pad 122. The first lower pad 122 may electrically connect the first conductive pattern 112 and the first connection member 140a and electrically connect the first conductive pattern 112 and the second connection member 140b. The first lower pad 122 may electrically connect the second conductive pattern 114 and the third connection member 140c.

The first lower passivation film 120 and the first upper passivation film 130 may include, for example, a photoimageable dielectric (PID) material, but is not limited thereto.

Each of the first connection member 140a, the second connection member 140b, the third connection member 140c, and the fourth connection member 140d may be disposed on the second surface 100b of the first substrate 100. The first, second, and third connection members 140a, 140b, and 140c may be electrically connected to the first conductive pattern 112 and/or second conductive pattern 114 in the first substrate 100. For example, the first and second connection members 140a and 140b may be electrically connected to the first conductive pattern 112, and the third connection member 140c may be electrically connected to the second conductive pattern 114.

A plurality of first conductive patterns 112 may be formed in the first insulating layer 110. The plurality of first conductive patterns 112 may form a daisy chain structure. The plurality of first conductive patterns 112 may be a portion (e.g., a subset) of a first closed circuit. The first closed circuit may include, for example, the plurality of first conductive patterns 112, a plurality of (e.g., two of the) first connection members 140a (on the lower surface of the first insulating layer 110), a plurality of first upper pads 132 (on the upper surface of the first insulating layer 110), a plurality of first bumps 160 (on the plurality of first upper pads 132, respectively), and a plurality of third conductive patterns 116 in the first semiconductor chip 150.

The plurality of first conductive patterns 112 may transfer an electrical signal to the first semiconductor chip 150 by electrically connecting one among the plurality of first connection members 140a (e.g., a first sub connection member 140a_1 or a second sub connection member 140a_2, which will be described later) and one among the plurality of first upper pads 132. The one among the plurality of first upper pads 132 may be electrically connected to the first semiconductor chip 150 via one among the plurality of first bumps 160. The electrical signal may be transferred from the first semiconductor chip 150 to another one among the plurality of first connection members 140a (e.g., the second sub connection member 140a_2 or the first sub connection member 140a_1, which will be described later) via another one among the plurality of first bumps 160, another one among the plurality of first upper pads 132, and the plurality of first conductive patterns 112.

For example, a current entering any one among the plurality of first connection members 140a may flow to another one among the plurality of first connection members 140a through the plurality of first conductive patterns 112 and the first semiconductor chip 150.

Likewise, the plurality of first conductive patterns 112 may be a portion (e.g., subset) of a second closed circuit with a plurality of (e.g., two of the) second connection members 140b and a plurality of fourth conductive patterns 118 in the first semiconductor chip 150. The second closed circuit may include, for example, the plurality of first conductive patterns 112, the plurality of second connection members 140b (on the lower surface of the first insulating layer 110), the plurality of first upper pads 132 (on the upper surface of the first insulating layer 110), the plurality of first bumps 160 (on the plurality of first upper pads 132, respectively), and the plurality of fourth conductive patterns 118 in the first semiconductor chip 150.

The plurality of first conductive patterns 112 may transfer an electrical signal to the first semiconductor chip 150 by electrically connecting one among the plurality of second connection members 140b (e.g., a third sub connection member 140b_1 or a fourth sub connection member 140b_2, which will be described later) and one among the plurality of first upper pads 132. The one among the plurality of first upper pads 132 may be electrically connected to the first semiconductor chip 150 via one among the plurality of first bumps 160. The electrical signal may be transferred from the first semiconductor chip 150 to another one among the plurality of second connection members 140b (e.g., the fourth sub connection member 140b_2 or the third sub connection member 140b_1, which will be described later) via another one among the plurality of first bumps 160, another one among the plurality of first upper pads 132, and the plurality of first conductive patterns 112.

For example, a current entering any one among the plurality of second connection members 140b may flow to another one among the plurality of second connection members 140b through the plurality of first conductive patterns 112 and the first semiconductor chip 150. In some embodiments, the elements included in the first closed circuit and the second closed circuit may exclude each other. For example, a first upper pad 132 among the plurality of first upper pads 132 in the first closed circuit may be different from a first upper pad 132 among the plurality of first upper pads 132 in the second closed circuit.

The second conductive pattern 114 may be formed in the first insulating layer 110. The second conductive pattern 114 may form a daisy chain structure. The second conductive pattern 114 may electrically connect a plurality of circuit patterns 134 with the third connection member 140c.

In the semiconductor package (e.g., the semiconductor package 1000 in FIG. 1) according to some embodiments, the first conductive pattern 112 and the second conductive pattern 114 may not be electrically connected to each other. In detail, the first conductive pattern 112 and the second conductive pattern 114 in the first substrate 100 may not be electrically connected to each other. For example, the current applied to the first connection member 140a may flow to the first conductive pattern 112 and may not flow to the second conductive pattern 114. The first conductive pattern 112 and the second conductive pattern 114 may be electrically insulated (e.g., electrically disconnected) from each other. For example, the second conductive pattern 114 may be (electrically) separated (e.g., insulated) from the first semiconductor chip 150.

In FIG. 2, the circuit pattern 134 is shown as being connected (e.g., electrically connected) to the second conductive pattern 114, but this is to be construed as an example.

The first insulating layer 110 is shown as a single layer, but this is only for convenience of description. For example, the first insulating layer 110 may be formed of a multilayer, and each of the first conductive pattern 112 and the second conductive pattern 114 may be formed of a multilayer.

The first, second, third, and fourth connection members 140a, 140b, 140c, and 140d may be spherical or elliptical (in a plan view), for example, but are not limited thereto. The first, second, third, and fourth connection members 140a, 140b, 140c, and 140d may include, but are not limited to, tin (Sn), indium (In), bismuth (Bi), antimony (Sb), copper (Cu), silver (Ag), zinc (Zn), lead (Pb) and/or their combination.

The first, second, third, and fourth connection members 140a, 140b, 140c, and 140d may electrically connect the first substrate 100 to an external device. Therefore, the first, second, third, and fourth connection members 140a, 140b, 140c, and 140d may provide an electrical signal to the first substrate 100 or provide the electrical signal provided from the first substrate 100 to the external device. For example, the controller 2000 of FIG. 1 may provide the electrical signal to the semiconductor package 1000 through the first, second, third, and/or fourth connection members 140a, 140b, 140c, and/or 140d in the semiconductor package 1000. For example, the controller 2000 of FIG. 1 may be electrically connected to the first, second, third, and/or fourth connection members 140a, 140b, 140c, and/or 140d. As used hereinafter, the terms “external/outside configuration”, “external/outside device”, “external/outside power”, “external/outside signal”, or “outside” are intended to broadly refer to a device, circuit, block, module, power, and/or signal that resides externally (e.g., outside of a functional or physical boundary) with respect to a given circuit, block, module, system, or device.

The first semiconductor chip 150 may be disposed on the first substrate 100. For example, the first semiconductor chip 150 may be packaged on the upper surface of the first substrate 100. The first semiconductor chip 150 may be an integrated circuit (IC) in which hundreds to millions of semiconductor devices are integrated in one chip. For example, the first semiconductor chip 150 may be, but is not limited to, an application processor (AP), a Central Processing Unit (CPU), a Graphic Processing Unit (GPU), a Field Programmable Gate Array (FPGA), a digital signal processor, an encryption processor, a microprocessor, and/or a microcontroller. For example, the first semiconductor chip 150 may be a logic chip such as an analog digital converter (ADC) or an application specific IC (ASIC), or may be a memory chip such as a volatile memory (e.g., DRAM) or a nonvolatile memory (e.g., ROM or flash memory). In addition, the first semiconductor chip 150 may include (be configured by) a combination of the logic chip and the memory chip.

Although only the first semiconductor chip 150 is shown as being formed on the first substrate 100, this is only for convenience of description. For example, a plurality of first semiconductor chips 150 may be disposed side by side on the first substrate 100, or a plurality of first semiconductor chips 150 may be sequentially stacked on the first substrate 100.

In some embodiments, the first semiconductor chip 150 may be packaged on the first substrate 100 by a flip chip bonding method. For example, the first bump 160 may be formed between the upper surface of the first substrate 100 and the lower surface of the first semiconductor chip 150. The first bump 160 may electrically connect the first substrate 100 and the first semiconductor chip 150.

The first bump 160 may include, for example, a first pillar layer 162 and a first solder layer 164.

The first pillar layer 162 may be protruded from the lower surface of the first semiconductor chip 150. The first pillar layer 162 may include, for example, copper (Cu), a copper alloy, nickel (Ni), a nickel alloy, palladium (Pd), platinum (Pt), gold (Au), cobalt (Co) and/or their combination, but is not limited thereto.

The first solder layer 164 may connect (e.g., electrically connect) the first pillar layer 162 and the first substrate 100. For example, the first solder layer 164 may be connected (e.g., electrically connected) to a portion of the first upper pads 132. The first solder layer 164 may be, for example, spherical or elliptical (in a plan view), but is not limited thereto. The first solder layer 164 may include, for example, tin (Sn), indium (In), bismuth (Bi), antimony (Sb), copper (Cu), silver (Ag), zinc (Zn), lead (Pb) and/or their combination, but is not limited thereto.

Although not shown, an underfill may be disposed between the first substrate 100 and the first semiconductor chip 150. The underfill may be on (e.g., extend around, cover, or overlap) the first bump 160, the first upper pad 132, and the circuit pattern 134. The underfill may include, for example, an insulating polymer material such as an epoxy molding compound (EMC), but is not limited thereto. The underfill may include an insulating material having excellent fluidity.

Referring back to FIGS. 1 to 3, the semiconductor package 1000 may include a daisy chain circuit. For example, the first conductive pattern 112 and the second conductive pattern 114 may constitute the daisy chain circuit.

The first connection member 140a may include a first sub connection member 140a_1 and a second sub connection member 140a_2. The first sub connection member 140a_1 may be an input terminal that receives an electrical signal from the controller 2000. The second sub connection member 140a_2 may be an output terminal that sends the electrical signal to the controller 2000. That is, a closed circuit (e.g., the first closed circuit) may be configured in which the electrical signal applied to the first sub connection member 140a_1 may be output from the second sub connection member 140a_2 through the first conductive pattern 112 and the circuit pattern in the first semiconductor chip 150 (e.g., the third conductive pattern 116 in the first semiconductor chip 150).

The controller 2000 may measure a current value flowing in the closed circuit (e.g., the first closed circuit) by selecting the first sub connection member 140a_1 and the second sub connection member 140a_2. The controller 2000 or the user may detect open of the closed circuit (e.g., the first closed circuit) based on the measured current value. Herein, the term “selecting A and B” may mean “measuring a current of a circuit between A and B”.

The second connection member 140b may include a third sub connection member 140b_1 and a fourth sub connection member 140b_2. The third sub connection member 140b_1 may be an input terminal that receives the electrical signal from the controller 2000. The fourth sub connection member 140b_2 may be an output terminal that sends the electrical signal to the controller 2000. That is, a closed circuit (e.g., the second closed circuit) may be configured in which the electrical signal applied to the third sub connection member 140b_1 is output from the fourth sub connection member 140b_2 through the first conductive pattern 112 and the circuit pattern in the first semiconductor chip 150 (e.g., the fourth conductive pattern 118 in the first semiconductor chip 150).

The controller 2000 may measure a current value flowing in the closed circuit (e.g., the second closed circuit) by selecting the third sub connection member 140b_1 and the fourth sub connection member 140b_2. The controller 2000 or the user may detect open of the closed circuit (e.g., the second closed circuit) based on the measured current value.

The controller 2000 may measure a current value by selecting any one of the first sub connection member 140a_1 and the second sub connection member 140a_2 and any one of the third sub connection member 140b_1 and the fourth sub connection member 140b_2. The controller 2000 or the user may detect a short based on the measured current value.

The controller 2000 may measure a current value by selecting any one of the first, second, third, and fourth sub connection members 140a_1, 140a_2, 140b_1, and 140b_2 and the third connection member 140c. The controller 2000 or the user may detect a short based on the measured current value. For example, the controller 2000 may measure a current value by selecting (between) the first sub connection member 140a_1 and the third connection member 140c. When the measured current value is greater than or equal to a reference value, it may be determined as a short. In this case, whether a short occurs between the first upper pad 132 and the circuit pattern 134 may be detected.

As the semiconductor package is miniaturized, pitches of the bumps of the substrate and the flip chip package may be reduced. Therefore, a solder resist for protecting the bumps may be removed, and the bumps and the PCB circuit pattern may be exposed. In this case, a short may occur between the bumps. Further, a short may occur between the bumps and the PCB circuit pattern adjacent to the bumps.

The semiconductor package and the electronic device including the same according to some embodiments of the present disclosure may detect whether a short occurs between the bumps and between the bumps and the PCB circuit pattern. Therefore, durability and reliability of the semiconductor package may be improved.

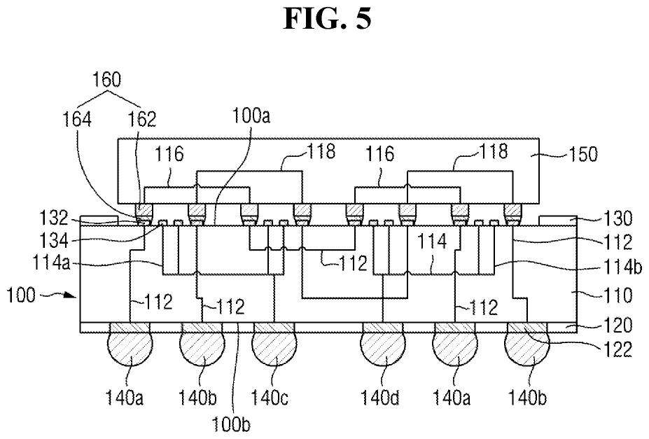

FIG. 5 is an example cross sectional view illustrating a semiconductor package according to some embodiments. For convenience of description, the following description will be based on differences from those described with reference to FIGS. 1 to 4.

Referring to FIG. 5, the first substrate 100 may include a fifth conductive pattern 114a and a sixths conductive pattern 114b.

The description of the fifth conductive pattern 114a may be similar to the second conductive pattern 114 of FIG. 2. Hereinafter, the fifth conductive pattern 114a will be described based on differences from the second conductive pattern 114 of FIG. 2.

The fifth conductive pattern 114a may be electrically connected to a portion (e.g., a subset) of the circuit pattern 134. The fifth conductive pattern 114a may electrically connect the portion (e.g., a subset) of the circuit pattern 134 and the third connection member 140c.

The sixths conductive pattern 114b may be electrically connected to another portion (e.g., another subset) of the circuit pattern 134 remaining after the electrical connection between the fifth conductive pattern 114a and the portion (e.g., the subset) of the circuit pattern 134. The sixths conductive pattern 114b may electrically connect (the another subset of) the circuit pattern 134 and the fourth connection member 140d.

The controller 2000 may measure a current value by selecting any one of the first, second, third, and fourth sub connection members 140a_1, 140a_2, 140b_1, and 140b_2 and the third connection member 140c. The controller 2000 may detect whether a short occurs between the first upper pad 132 and the circuit pattern 134 to which the third connection member 140c is connected (e.g., electrically connected), based on the measured current value.

The controller 2000 may measure a current value by selecting any one of the first, second, third, and fourth sub connection members 140a_1, 140a_2, 140b_1, and 140b_2 and the fourth connection member 140d. The controller 2000 may detect whether a short occurs between the first upper pad 132 and the circuit patterns 134 to which the fourth connection member 140d is connected (e.g., electrically connected), based on the measured current value.

As the semiconductor package is miniaturized, a conductive wiring layer in the substrate may also be miniaturized and integrated. Therefore, there may be a limitation in a space of the substrate, in which the conductive wiring layer may be formed. As a result, it may be difficult to configure a single conductive wiring layer for detecting a short between the PCB circuit and another element.

On the other hand, the semiconductor package according to some embodiments of the present disclosure may overcome the spatial limitation by dividing the conductive pattern (e.g., the second conductive pattern 114) in the substrate (e.g., the first substrate 100) into the fifth conductive pattern 114a and the sixths conductive pattern 114b.

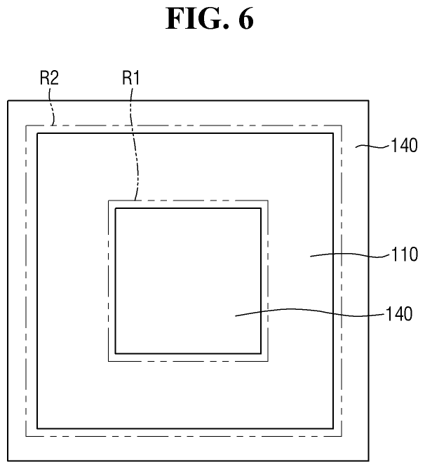

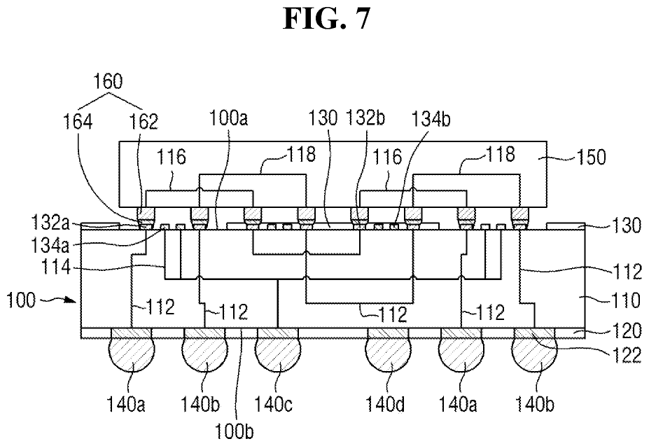

FIGS. 6 and 7 are example views illustrating a semiconductor package according to some embodiments. FIG. 6 is a plan view illustrating the first substrate 100 to describe a semiconductor package (e.g., the semiconductor package 1000 in FIG. 1) according to some embodiments. FIG. 7 is a cross sectional view illustrating a semiconductor package (e.g., the semiconductor package 1000 in FIG. 1) according to some embodiments. For convenience of description, the following description will be based on differences from those described with reference to FIGS. 1 to 4. Referring to FIGS. 6 and 7, the first upper pad 132 may include a first sub upper pad 132a and a second sub upper pad 132b. Referring to FIGS. 6 and 7, the circuit pattern 134 may include a first sub circuit pattern 134a and a second sub circuit pattern 134b.

Referring to FIGS. 6 and 7, the first substrate 100 may include a first region R1 and a second region R2.

The first region R1 may be disposed on the first surface 100a of the first substrate 100. The second region R2 may be disposed on the first surface 100a of the first substrate 100. The second region R2 may be disposed around the first region R1. For example, the second region R2 may extend around (e.g., surround) the first region R1 in a plan view.

The first upper passivation film 130 may be disposed on the first region R1. The first upper passivation film 130 may not be disposed on the second region R2. The first upper passivation film 130 may be disposed outside the second region R2.

In the first region R1, the first upper passivation film 130 may extend around (e.g., surround) the second sub upper pad 132b and the second sub circuit pattern 134b. In the first region R1, the first upper passivation film 130 may extend around (e.g., surround or cover) a portion where the first upper pad 132 (e.g., the second sub upper pad 132b) and the first bump 160 are in contact with each other. The second sub circuit pattern 134b disposed in the first region R1 may not be connected (e.g., not be electrically connected) to the third connection member 140c, but is not limited thereto. Unlike the shown example, the second sub circuit pattern 134b disposed in the first region R1 may be electrically connected to the third connection member 140c and/or the fourth connection member 140d.

The first upper passivation film 130 may not be disposed in the second region R2. The first upper passivation film 130 may expose the first sub upper pad 132a and the first sub circuit pattern 134a, which are disposed in the second region R2. The description of the first sub upper pad 132a and the first sub circuit pattern 134a, which are disposed in the second region R2, may be substantially the same as the first upper pad 132 and the circuit pattern 134 described with reference to FIG. 2, respectively.

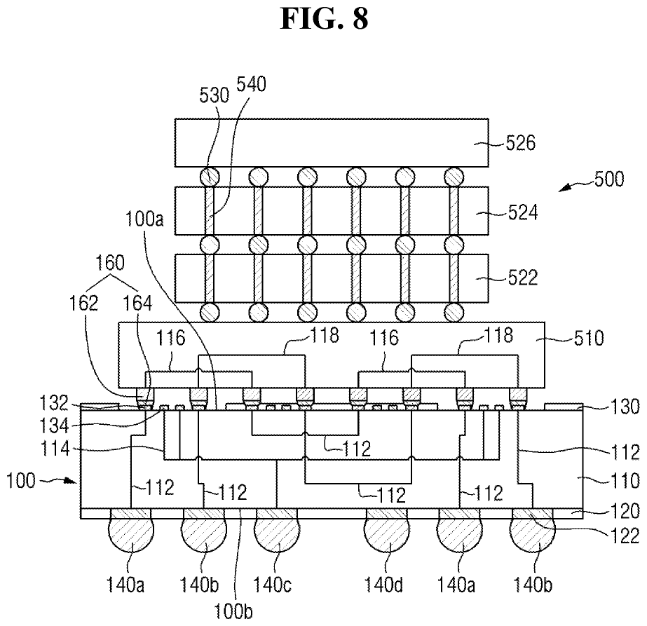

FIG. 8 is an example view illustrating a semiconductor package according to some embodiments. For convenience of description, the following description will be based on differences from those described with reference to FIGS. 1 to 4 (e.g., the semiconductor package 1000 in FIG. 1).

Referring R to FIG. 8, in the semiconductor package according to some embodiments, a high bandwidth memory (HBM) 500 may be packaged. The high bandwidth memory 500 may include, for example, a controller chip 510 and a plurality of memory chips 522, 524, and 526. The controller chip 510 may be packaged on the first surface 100a of the first substrate 100, and the plurality of memory chips 522, 524, and 526 may be sequentially stacked on the controller chip 510. The controller chip 510 may be a logic chip, and the plurality of memory chips 522, 524, and 526 may be memory chips. The controller chip 510 may correspond to the first semiconductor chip 150 in FIGS. 2, 5, and 7.

In some embodiments, the high bandwidth memory 500 may include a second bump 530 and a through via 540. The second bump 530 may be interposed between the controller chip 510 and the plurality of memory chips 522, 524, and 526. For example, the second bump 530 may be disposed between each of the plurality of memory chips 522, 524, and 526. The through via 540 may be connected (e.g., electrically connected) to the second bump 530 by extending in (e.g., passing through or penetrating) at least a portion of the plurality of memory chips 522, 524, and 526 and/or (although not shown in FIG. 8) the controller chip 510. Therefore, the high bandwidth memory 500 may be (although not shown in FIG. 8) electrically connected to the first substrate 100.

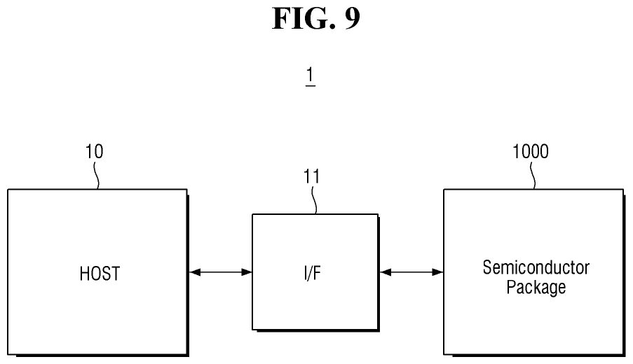

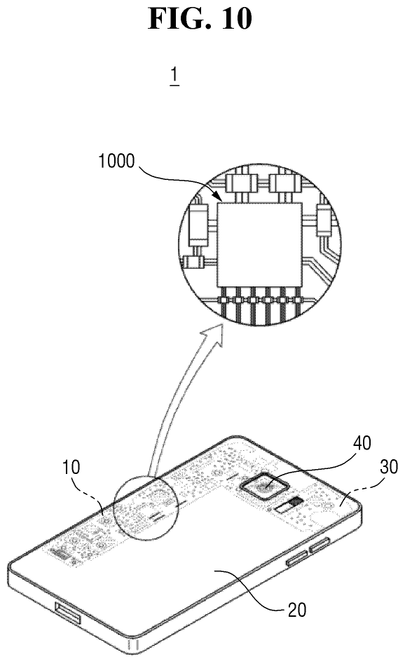

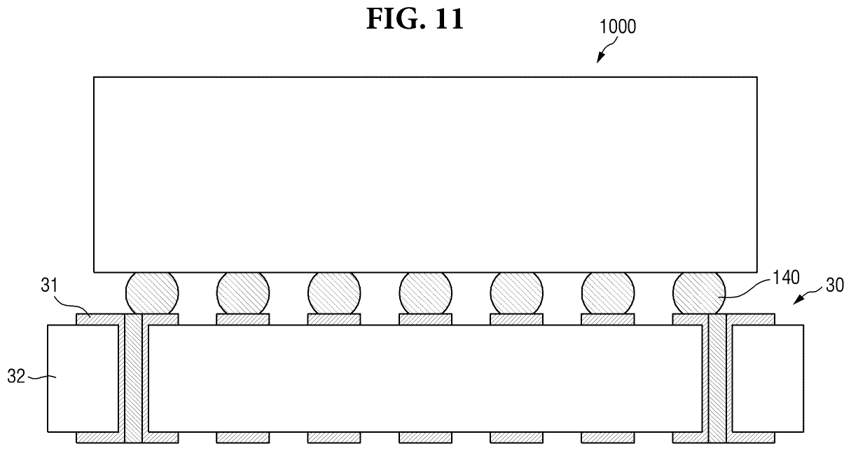

FIG. 9 is a view illustrating an electronic device according to some embodiments. FIG. 10 is a view illustrating an electronic device according to some embodiments. FIG. 11 is a view illustrating a semiconductor package and a main board of FIG. 10

Referring to FIG. 9, an electronic device 1 may include a host 10, an interface 11, and a semiconductor package 1000.

In some embodiments, the host 10 may be connected (e.g., electrically connected) to the semiconductor package 1000 through the interface 11. For example, the host 10 may control the semiconductor package 1000 by transferring a signal to the semiconductor package 1000. Also, for example, the host 10 may receive a signal from the semiconductor package 1000 and process data included in the signal.

For example, the host 10 may include a Central Processing Unit (CPU), a controller or an Application Specific Integrated Circuits (ASIC). Also, for example, the host 10 may include a memory chip such as a Dynamic Random Access Memory (DRAM), a Static RAM (SRAM), a Phase Change RAM (PRAM), a Magneto Resistive RAM (MRAM), a Ferroelectric RAM (FeRAM) and a Resistive RAM (RRAM).

Referring to FIGS. 9 and 10, the electronic device 1 may include a host 10, a body 20, a main board 30, a camera module 40, and a semiconductor package 1000.

The main board 30 may be packaged in the body 20 of the electronic device 1. The host 10, the camera module 40, and the semiconductor package 1000 may be packaged on the main board 30. The host 10, the camera module 40, and the semiconductor package 1000 may be electrically connected to one another by the main board 30. For example, the interface 11 may be implemented by the main board 30. For example, the main board 30 may include the interface 11.

The host 10 and the semiconductor package 1000 may be electrically connected to each other by the main board 30 to exchange signals.

Referring to FIG. 11, the semiconductor package 1000 may be disposed on the main board 30. For example, the first connection terminal 105 may be disposed on the main board 30. The main board 30 may be connected (e.g., electrically connected) to the semiconductor package 1000 by the first connection terminal 105.

The main board 30 may be a printed circuit board (PCB) wiring structure, a ceramic wiring structure, a glass wiring structure, or the like, but the embodiments according to the technical scopes of the present disclosure are not limited thereto. For convenience of description, it is assumed that the main board 30 is the PCB wiring structure.

The main board 30 may include a connection structure 31 and a core 32. The core 32 may include, for example, a Copper Clad Laminate (CCL), PPG, Ajinomoto Build up Film (ABF), epoxy, polyimide, etc. The connection structure 31 may include, for example, copper (Cu), aluminum (Al), silver (Ag), tin (Sn), gold (Au), nickel (Ni), lead (Pb), titanium (Ti) and/or their alloy, but is not limited thereto.

The core 32 may be disposed in a central portion of the main board 30, and the connection structure 31 may be disposed on upper and the lower portions of the core 32. The connection structure 31 may be disposed to be exposed to upper and lower portions of the main board 30.

Also, the connection structure 31 may be disposed by extending in (e.g., passing through or penetrating) the core 32. The connection structure 31 may electrically connect devices, which are in contact with the main board 30, with each other. For example, the connection structure 31 may electrically connect the semiconductor package 1000 with the host 10. That is, the connection structure 31 may electrically connect the semiconductor package 1000 with the host 10 through the first connection terminal 105.

In concluding the detailed description, those skilled in the art will appreciate that many variations and modifications may be made to the preferred embodiments without substantially departing from the principles of the present inventive concept. Therefore, the disclosed preferred embodiments of the invention are used in a generic and descriptive sense only and not for purposes of limitation.

What is claimed is:

1. A semiconductor package comprising:
a substrate that includes a first surface and a second surface, wherein the second surface is opposite to the first surface;
a first connection member and a second connection member on the second surface of the substrate;
an upper pad on the first surface of the substrate, wherein the upper pad is electrically connected to the first connection member;
a circuit pattern on the first surface of the substrate, wherein the circuit pattern is electrically connected to the second connection member;
an upper passivation film on the first surface of the substrate, wherein the upper passivation film at least partially exposes the upper pad and the circuit pattern;
a bump on the upper pad; and
a semiconductor chip on the bump.

2. The semiconductor package of claim 1, further comprising: a first conductive pattern and a second conductive pattern in the substrate,
wherein the first conductive pattern electrically connects the first connection member and the upper pad, and
wherein the second conductive pattern electrically connects the second connection member and the circuit pattern.

3. The semiconductor package of claim 2, wherein the first conductive pattern and the second conductive pattern are electrically insulated from each other.

4. The semiconductor package of claim 1, wherein a distance of the upper passivation film from the first surface of the substrate in a first direction perpendicular to the first surface of the substrate is greater than a distance of the upper pad from the first surface of the substrate in the first direction.

5. The semiconductor package of claim 1, wherein a distance of the upper passivation film from the first surface of the substrate in a first direction perpendicular to the first surface of the substrate is greater than a distance of the circuit pattern from the first surface of the substrate in the first direction.

6. The semiconductor package of claim 1, wherein the upper pad includes an oblong shape in a plan view.

7. The semiconductor package of claim 1, wherein the bump includes a solder layer and a pillar layer on the solder layer, and
wherein the solder layer is in contact with the upper pad.

8. The semiconductor package of claim 1, further comprising: a third connection member on the second surface of the substrate,
wherein the third connection member is electrically connected to a subset of the circuit pattern.

9. An electronic device comprising:
a semiconductor package; and
a controller that is electrically connected to the semiconductor package, wherein the controller is configured to measure a current of the semiconductor package,
wherein the semiconductor package comprises:
a substrate that includes a first surface and a second surface, wherein the second surface is opposite to the first surface;
a circuit pattern and a plurality of upper pads on the first surface of the substrate;
an upper passivation film on the first surface of the substrate;
a first connection member on the second surface of the substrate, wherein the first connection member is electrically connected to the plurality of upper pads;
a second connection member on the second surface of the substrate, wherein the second connection member is electrically connected to the circuit pattern; and
each of the first connection member and the second connection member is electrically connected to the controller.

10. The electronic device of claim 9, further comprising: a daisy chain circuit in the substrate,
wherein the daisy chain circuit includes a first conductive pattern and a second conductive pattern,
wherein the first conductive pattern is electrically connected to the first connection member, and
wherein the second conductive pattern is electrically connected to the second connection member.

11. The electronic device of claim 10, wherein the first connection member includes a first sub connection member and a second sub connection member, and
wherein the first conductive pattern electrically connects the first sub connection member and the second sub connection member.

12. The electronic device of claim 11, wherein the controller is configured to measure a current between the first sub connection member and the second connection member or a current between the second sub connection member and the second connection member.

13. The electronic device of claim 9, wherein the upper passivation film at least partially exposes the plurality of upper pads and the circuit pattern.

14. The electronic device of claim 9, wherein the substrate includes a first region and a second region that extends around the first region in a plan view,
wherein the first region includes a portion of the upper passivation film, a subset of the plurality of upper pads, and a subset of the circuit pattern, and
wherein the portion of the upper passivation film extends around the subset of the plurality of upper pads and the subset of the circuit pattern.

15. The electronic device of claim 9, further comprising: a bump on one of the plurality of upper pads; and
a semiconductor chip on the bump.

16. The electronic device of claim 9, wherein a distance of the upper passivation film from the first surface of the substrate in a first direction that is perpendicular to the first surface of the substrate is greater than a distance of one of the plurality of upper pads from the first surface of the substrate in the first direction.

17. The electronic device of claim 9, further comprising: a third connection member on the second surface of the substrate,
wherein the third connection member is electrically connected to a subset of the plurality of upper pads, and
wherein the controller is configured to measure a current between two among the first connection member, the second connection member, and the third connection member.

18. The electronic device of claim 9, further comprising:
a plurality of lower pads on the second surface of the substrate; and
a lower passivation film on the second surface of the substrate,
wherein the lower passivation film at least partially exposes the plurality of lower pads, and
wherein the first connection member and the second connection member are on the plurality of lower pads, respectively.

19. The electronic device of claim 9, wherein the plurality of upper pads includes an oblong shape in a plan view.

20. An electronic device comprising:
a semiconductor package; and
a controller that is electrically connected to the semiconductor package and is configured to measure a current in the semiconductor package,
wherein the semiconductor package comprises
a substrate that includes a first surface and a second surface, wherein the second surface is opposite to the first surface;
a circuit pattern and a plurality of upper pads on the first surface of the substrate;
an upper passivation film on the first surface of the substrate, wherein the upper passivation film at least partially exposes the circuit pattern and the plurality of upper pads;
a first connection member on the second surface of the substrate, wherein the first connection member is electrically connected to a subset of the plurality of upper pads;
a second connection member on the second surface of the substrate, wherein the second connection member is electrically connected to the circuit pattern; and
a daisy chain circuit in the substrate,
wherein the daisy chain circuit includes a first conductive pattern and a second conductive pattern,
wherein the first conductive pattern is electrically connected to the first connection member,
wherein the second conductive pattern is electrically connected to the second connection member, and
wherein the controller is configured to measure a current between the first connection member and the second connection member.
